(19) United States
(12) Patent Application Publication
(10) Pub. No.: US 2025/0160143 A1
(43) Pub. Date: May 15, 2025

(54) ARRAY SUBSTRATE AND DISPLAY PANEL

(71) Applicant: Wuhan China Star Optoelectronics Technology Co., Ltd., Wuhan (CN)

(72) Inventors: Fei AI, Wuhan (CN); Shiyu LONG, Wuhan (CN)

(21) Appl. No.: 17/635,074

(22) PCT Filed: Jan. 20, 2022
(86) PCT No.: PCT/CN2022/072917

§ 371 Date: Oct. 10, 2024

(30) Foreign Application Priority Data
Jan. 13, 2022 (CN) 202210037851.8

(51) Int. Cl. H10K 59/131; H10K 59/12

(52) U.S. Cl. CPC H10K 59/131; H10K 59/1201

(57) ABSTRACT

An array substrate and a display panel are disclosed. In the array substrate, a first metal layer includes a first connection segment and a second connection segment, or a second metal layer includes a first connection segment and a second connection segment. The array substrate further includes a first via hole defined above a sheltering-and-wiring metal layer and a second via hole defined above a shielding metal layer, and the first connection segment passes through the first via hole to connect with the sheltering-and-wiring metal layer and the second connection segment passes through the second via hole to connect with the shielding metal layer.

### FIELD OF INVENTION

The present disclosure relates to a field of display, and more particularly to an array substrate and a display panel.

### BACKGROUND OF DISCLOSURE

With the developments of communication technology and virtual reality technology, the resolution requirements for display panels are getting higher and higher.

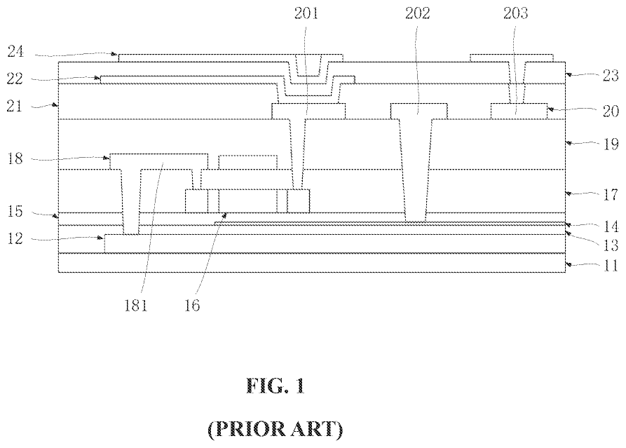

Currently, in the high-resolution display panel such as resolution greater than 1000 ppi, as shown in FIG. 1, which is a schematic diagram of the structure of an array substrate of a high-resolution display panel, the array substrate includes stacked layers of a base 11, a sheltering layer 12, a first insulating layer 13, a shielding layer 14, a second insulating layer 15, a semiconductor layer 16, a third insulating layer 17, a first metal layer 18, a fourth insulating layer 19, a second metal layer 20, a fifth insulating layer 21, a third metal layer 22, a sixth insulating layer 23, and a fourth metal layer 24, wherein the first metal layer 18 includes a first connecting portion 181 connecting with the semiconductor layer 16 and the sheltering layer 12 at both ends, respectively, and the second metal layer 20 includes a second connecting portion 201 respectively connecting with the semiconductor layer 16 and the third metal layer 22, a third connecting portion 202 connecting with the fourth metal layer 24, and a fourth connecting portion 203 connecting with the shielding layer 14. Apparently, the structure of the array substrate is more complex, and each functional film layer has to be connected to each other through different via holes, such that up to 15 photomask processes are required for the production of the array substrate. Such numerous process steps would result in higher production costs.

### SUMMARY OF INVENTION

### Technical Issue

Embodiments of the present application provide an array substrate and a display panel in order to solve the technical problems of higher production costs caused by numerous process steps in manufacturing an array substate of a high-resolution display panel.

### Solution for Issue

### Technical Solution

An embodiment of the present application provides an array substrate. The array substrate comprises a display area and a peripheral area adjacent to the display area, and the array substrate comprises:
a base comprising stacked layers of a substrate, a sheltering-and-wiring metal layer, a buffer layer, a shielding metal layer, and a blocking insulation layer;
an active layer disposed on the base, wherein the active layer comprises an active segment and a first conductor segment and a second conductor segment disposed at two ends of the active segment;
a first insulation layer disposed on the base and the active layer;
a first metal layer disposed on the first insulation layer;
a second insulation layer disposed on the first insulation layer and the first metal layer;
a second metal layer disposed on the second insulation layer,
wherein the array substrate further comprises a first via hole defined above the sheltering-and-wiring metal layer, a second via hole defined above the shielding metal layer, a third via hole defined above the first conductor segment, a fourth via hole defined above the second conductor segment, and a first connection segment located within the display area and a second connection segment located within the peripheral area,
wherein an end of the first connection segment passes through the first via hole to connect with the sheltering-and-wiring metal layer, another end of the first connection segment passes through the third via hole to connect with the first conductor segment, the second connection segment passes through the second via hole to connect with the shielding metal layer, the second metal layer passes through the fourth via hole to connect with the second conductor segment,
wherein the first metal layer comprises the first connection segment and the second connection segment; or
the second metal layer comprises the first connection segment and the second connection segment.

In an array substrate provided by an embodiment of the present application, the first metal layer comprises the first connection segment and the second connection segment;
the first via hole passes through the first insulation layer, the blocking insulation layer, and the buffer layer, the second via hole passes through the first insulation layer and the blocking insulation layer, the third via hole passes through the first insulation layer, and the fourth via hole passes through the second insulation layer and the first insulation layer.

In an array substrate provided by an embodiment of the present application, the second metal layer comprises the first connection segment and the second connection segment;
the first via hole passes through the second insulation layer, the first insulation layer, the blocking insulation layer, and the buffer layer, the second via hole passes through the second insulation layer, the first insulation layer, and the blocking insulation layer, the third via hole and the fourth via hole both pass through the second insulation layer and the first insulation layer.

In an array substrate provided by an embodiment of the present application, the sheltering-and-wiring metal layer comprises a sheltering portion located within the display area and a data wiring connected with the sheltering portion and extending into the peripheral area;
the first via hole is opened above the sheltering portion, and an orthographic projection of the sheltering portion on the substrate covers an orthographic projection of the active layer on the substrate.

In an array substrate provided by an embodiment of the present application, the shielding metal layer comprises a shielding portion located within the display area and a shielded wiring connected with the shielding portion and extending into the peripheral area, the second via hole is defined above the shielded wiring;
the shielding portion is disposed between the active segment and the sheltering portion, and an orthographic projection of the shielding portion on the substrate covers an orthographic projection of the active segment on the substrate.

In an array substrate provided by an embodiment of the present application, the array substrate further comprises:
a third insulation layer disposed on the second insulation layer and the second metal layer;
a third metal layer disposed on the third insulation layer;
a fourth insulation layer disposed on the third metal layer;
a fourth metal layer disposed on the fourth insulation layer;
the second metal layer comprises a third connection segment passing through the fourth via hole and connected with the second conductor segment and a common electrode wiring located within the peripheral area, the array substrate comprises a fifth via hole defined above the third connection segment, a sixth via hole defined above the common electrode wiring, a pixel electrode connected with the third connection segment by the fifth via hole, and a common electrode connected with the common electrode wiring by the sixth via hole;
wherein the third metal layer comprises the pixel electrode and the fourth metal layer comprises the common electrode; or
the third metal layer comprises the common electrode and the fourth metal layer comprises the pixel electrode.

In an array substrate provided by an embodiment of the present application, the third metal layer comprises the pixel electrode and the fourth metal layer comprises the common electrode;
the fifth via hole passes through the third insulation layer, the sixth via hole passes through the fourth insulation layer and the third insulation layer, the pixel electrode passes through the fifth via hole to connect with the third connection segment, the common electrode passes through the sixth via hole to connect with the common electrode wiring;
a first concave portion located in the fifth via hole is defined by the pixel electrode, a second concave portion located in the first concave portion is defined by the fourth insulation layer, a third concave portion located in the second concave portion is defined by the common electrode;
the array substrate comprises an organic insulation layer disposed in the third concave portion.

In an array substrate provided by an embodiment of the present application, the sixth via hole comprises a first sub-hole passing through the third insulation layer and a second sub-hole passing through the fourth insulation layer and communicating with the first sub-hole;
the third metal layer further comprises a connecting portion disposed in the first sub-hole and connected with the common electrode wiring, the common electrode passes through the second sub-hole to connect with the connecting portion.

In an array substrate provided by an embodiment of the present application, the third metal layer comprises the common electrode and the fourth metal layer comprises the pixel electrode;
the fifth via hole and the sixth via hole both pass through the third insulation layer and the fourth insulation layer, the pixel electrode passes through the fifth via hole to connect with the third connection segment;
the array substrate further comprises a seventh via hole defined above the common electrode, the seventh via hole passes through the fourth insulation layer and locates within the peripheral area, the fourth metal layer further comprises a fourth connection segment, an end of the fourth connection segment passes through the sixth via hole to connect with the common electrode wiring, and another end of the fourth connection segment passes through the sixth via hole to connect with the common electrode wiring.

In an array substrate provided by an embodiment of the present application, the third insulation layer comprises a flat insulation sublayer disposed on the second insulation layer and an interlayer insulation sublayer disposed on the flat insulation sublayer and the second metal layer;
a thickness of the flat insulation sublayer is less than or equal to a thickness of the second metal layer.

Correspondingly, a display panel is also provided. The display panel comprises an array substrate, the array substrate comprises a display area and a peripheral area adjacent to the display area, and the array substrate comprises:
a base comprising stacked layers of a substrate, a sheltering-and-wiring metal layer, a buffer layer, a shielding metal layer, and a blocking insulation layer;
an active layer disposed on the base, wherein the active layer comprises an active segment and a first conductor segment and a second conductor segment disposed at two ends of the active segment;
a first insulation layer disposed on the base and the active layer;
a first metal layer disposed on the first insulation layer;
a second insulation layer disposed on the first insulation layer and the first metal layer;
a second metal layer disposed on the second insulation layer,
wherein the array substrate further comprises a first via hole defined above the sheltering-and-wiring metal layer, a second via hole defined above the shielding metal layer, a third via hole defined above the first conductor segment, a fourth via hole defined above the second conductor segment, and a first connection segment located within the display area and a second connection segment located within the peripheral area,
wherein an end of the first connection segment passes through the first via hole to connect with the sheltering-and-wiring metal layer, another end of the first connection segment passes through the third via hole to connect with the first conductor segment, the second connection segment passes through the second via hole to connect with the shielding metal layer, the second metal layer passes through the fourth via hole to connect with the second conductor segment,
wherein the first metal layer comprises the first connection segment and the second connection segment; or
the second metal layer comprises the first connection segment and the second connection segment.

In a display panel provided by an embodiment of the present application, the first metal layer comprises the first connection segment and the second connection segment;
the first via hole passes through the first insulation layer, the blocking insulation layer, and the buffer layer, the second via hole passes through the first insulation layer and the blocking insulation layer, the third via hole passes through the first insulation layer, and the fourth via hole passes through the second insulation layer and the first insulation layer.

In a display panel provided by an embodiment of the present application, the second metal layer comprises the first connection segment and the second connection segment;
the first via hole passes through the second insulation layer, the first insulation layer, the blocking insulation layer, and the buffer layer, the second via hole passes through the second insulation layer, the first insulation layer, and the blocking insulation layer, the third via hole and the fourth via hole both pass through the second insulation layer and the first insulation layer.

In a display panel provided by an embodiment of the present application, the sheltering-and-wiring metal layer comprises a sheltering portion located within the display area and a data wiring connected with the sheltering portion and extending into the peripheral area;
the first via hole is opened above the sheltering portion, and an orthographic projection of the sheltering portion on the substrate covers an orthographic projection of the active layer on the substrate.

In a display panel provided by an embodiment of the present application, the shielding metal layer comprises a shielding portion located within the display area and a shielded wiring connected with the shielding portion and extending into the peripheral area, the second via hole is defined above the shielded wiring;
the shielding portion is disposed between the active segment and the sheltering portion, and an orthographic projection of the shielding portion on the substrate covers an orthographic projection of the active segment on the substrate.

In a display panel provided by an embodiment of the present application, the array substrate further comprises:
a third insulation layer disposed on the second insulation layer and the second metal layer;
a third metal layer disposed on the third insulation layer;
a fourth insulation layer disposed on the third metal layer;
a fourth metal layer disposed on the fourth insulation layer;
the second metal layer comprises a third connection segment passing through the fourth via hole and connected with the second conductor segment and a common electrode wiring located within the peripheral area, the array substrate comprises a fifth via hole defined above the third connection segment, a sixth via hole defined above the common electrode wiring, a pixel electrode connected with the third connection segment by the fifth via hole, and a common electrode connected with the common electrode wiring by the sixth via hole;
wherein the third metal layer comprises the pixel electrode and the fourth metal layer comprises the common electrode; or
the third metal layer comprises the common electrode and the fourth metal layer comprises the pixel electrode.

In a display panel provided by an embodiment of the present application, the third metal layer comprises the pixel electrode and the fourth metal layer comprises the common electrode;
the fifth via hole passes through the third insulation layer, the sixth via hole passes through the fourth insulation layer and the third insulation layer, the pixel electrode passes through the fifth via hole to connect with the third connection segment, the common electrode passes through the sixth via hole to connect with the common electrode wiring;
a first concave portion located in the fifth via hole is defined by the pixel electrode, a second concave portion located in the first concave portion is defined by the fourth insulation layer, a third concave portion located in the second concave portion is defined by the common electrode;
the array substrate comprises an organic insulation layer disposed in the third concave portion.

In a display panel provided by an embodiment of the present application, the sixth via hole comprises a first sub-hole passing through the third insulation layer and a second sub-hole passing through the fourth insulation layer and communicating with the first sub-hole;
the third metal layer further comprises a connecting portion disposed in the first sub-hole and connected with the common electrode wiring, the common electrode passes through the second sub-hole to connect with the connecting portion.

In a display panel provided by an embodiment of the present application, the third metal layer comprises the common electrode and the fourth metal layer comprises the pixel electrode;
the fifth via hole and the sixth via hole both pass through the third insulation layer and the fourth insulation layer, the pixel electrode passes through the fifth via hole to connect with the third connection segment;
the array substrate further comprises a seventh via hole defined above the common electrode, the seventh via hole passes through the fourth insulation layer and locates within the peripheral area, the fourth metal layer further comprises a fourth connection segment, an end of the fourth connection segment passes through the sixth via hole to connect with the common electrode wiring, and another end of the fourth connection segment passes through the sixth via hole to connect with the common electrode wiring.

In a display panel provided by an embodiment of the present application, the third insulation layer comprises a flat insulation sublayer disposed on the second insulation layer and an interlayer insulation sublayer disposed on the flat insulation sublayer and the second metal layer;
a thickness of the flat insulation sublayer is less than or equal to a thickness of the second metal layer.

### Beneficial Effect of Invention

### Beneficial Effect

The beneficial effects of the present application are as follows: by disposing a first metal layer to include a first connection segment and a second connection segment or disposing a second metal layer to include a first connection segment and a second connection segment, and combining the structure in which an end of the first connection segment passes through a first via hole to connect with a sheltering-and-wiring metal layer with the structure in which the second connection segment passes through a second via hole to connect with the shielding metal layer, which represents that the first connection segment and the second connection segment are disposed at the same layer, a depth difference between the first via hole defined above the sheltering-and-wiring metal layer and the second via hole defined above the shielding metal layer would be smaller. In addition, the bottom of both the first via hole and the second via hole is a metal material layer such as the shielding metal layer or the sheltering-and-wiring metal layer, which has a certain performance of preventing the over-etching from the etching gas, therefore the first via hole and the second via hole can be made by the same photomask process, thereby reducing the number of photomasks and the production cost for manufacturing an array substrate.

### BRIEF DESCRIPTION OF DRAWINGS

### Description of Drawings

In order to more clearly illustrate the embodiments of the present disclosure or the technical solutions in prior arts, the following briefly introduces the accompanying drawings used in the embodiments. Obviously, the drawings in the following description merely show some of the embodiments of the present disclosure. As regards one of ordinary skill in the art, other drawings can be obtained in accordance with these accompanying drawings without making creative efforts.

FIG. 1 is a schematic diagram of the structure of an array substrate of prior art.

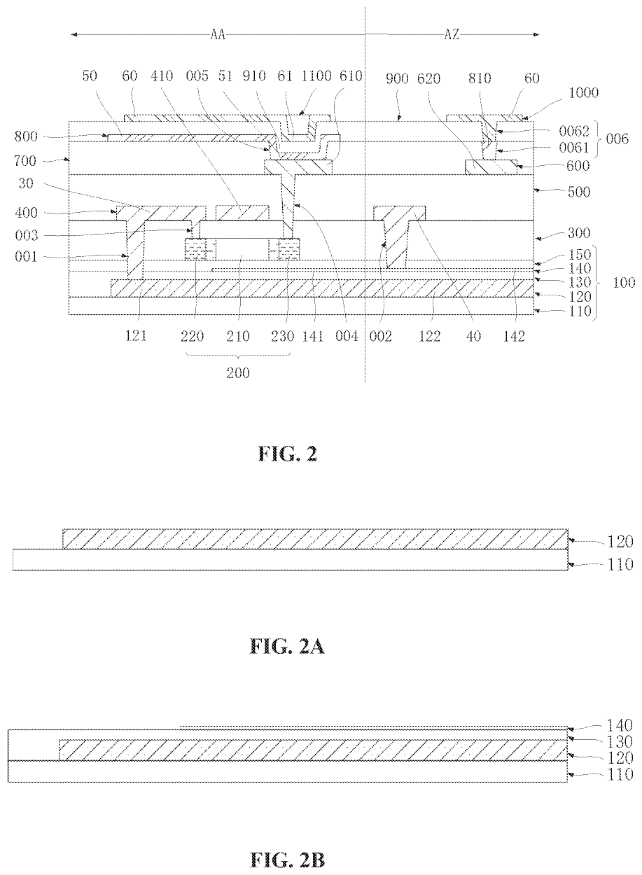

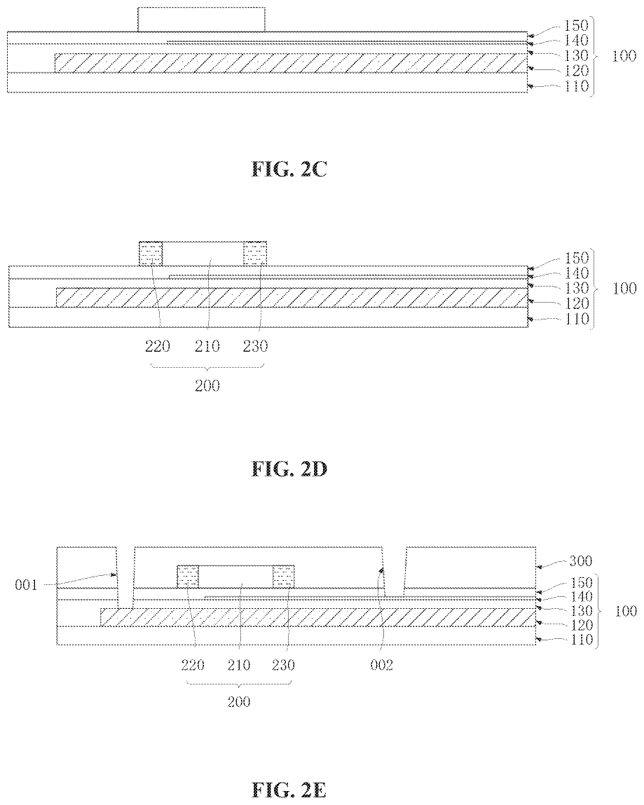

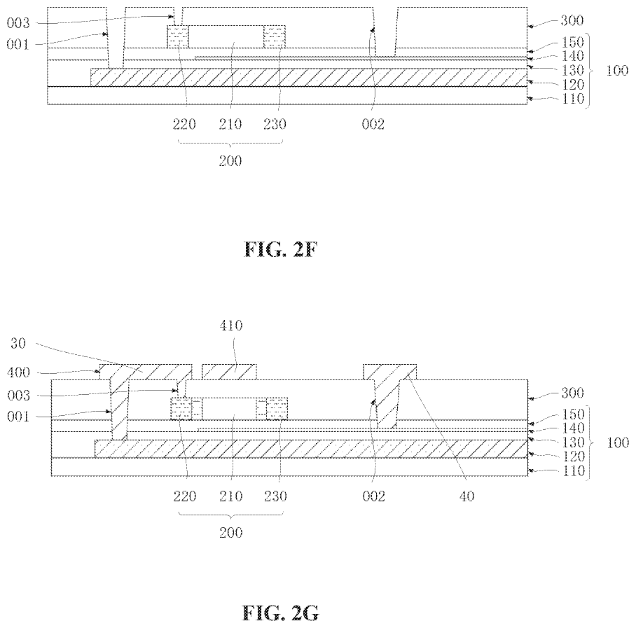

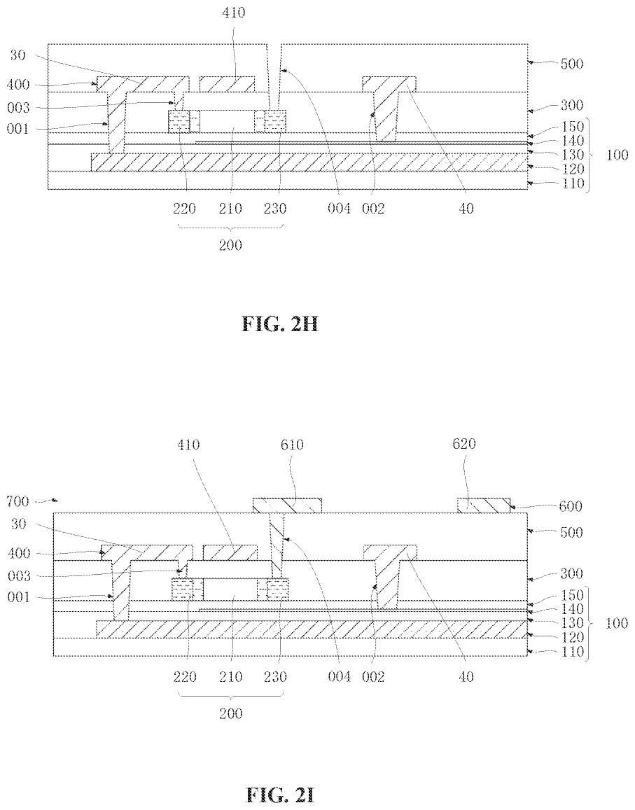

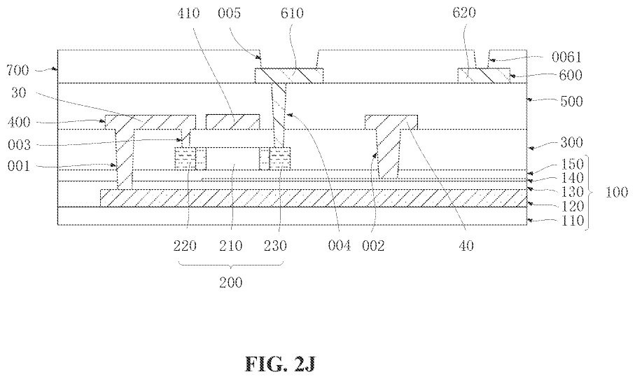

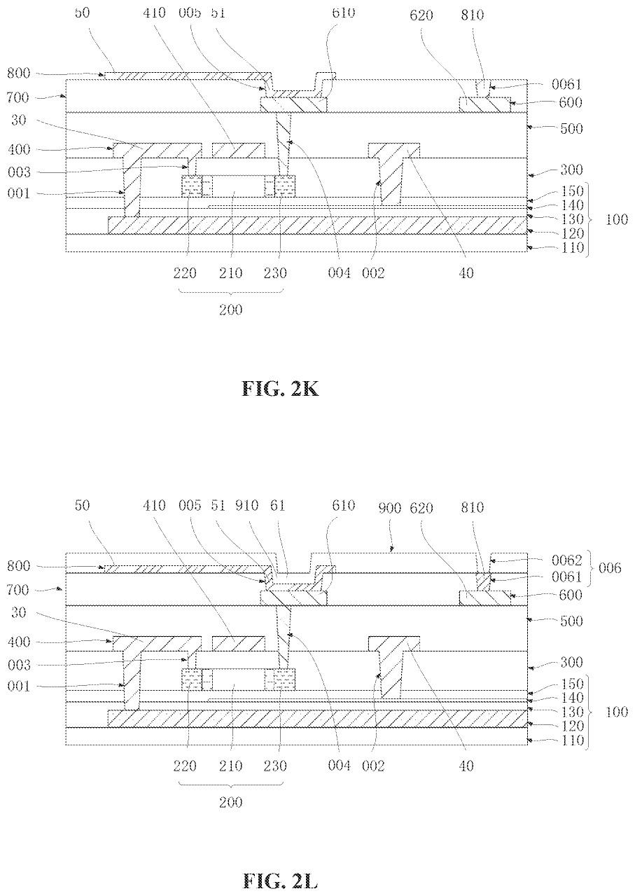

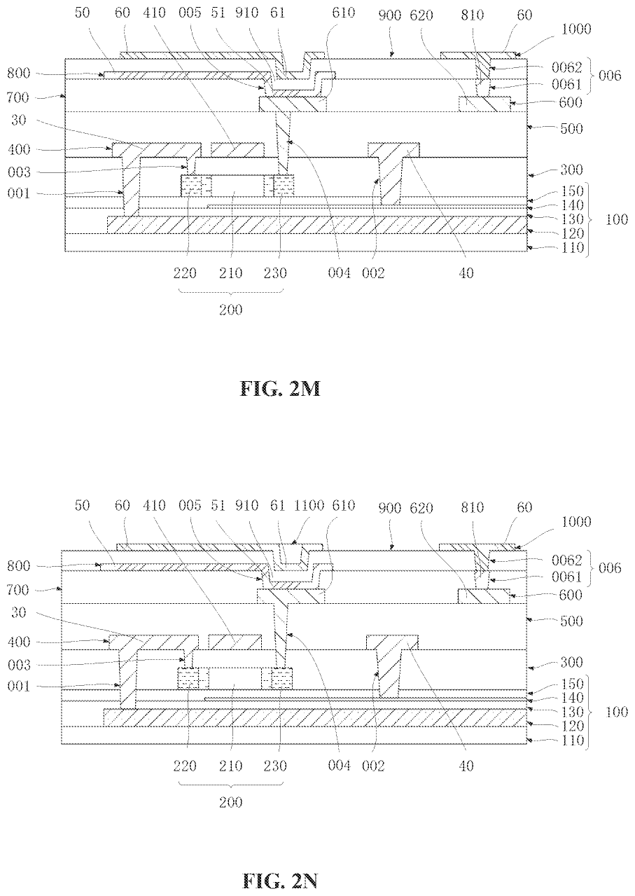

FIG. 2 is a schematic diagram of the first structure of an array substrate provided by an embodiment of the present application.

FIG. 2A to FIG. 2N are flowcharts of structural processes of manufacturing the array substrate shown in FIG. 2.

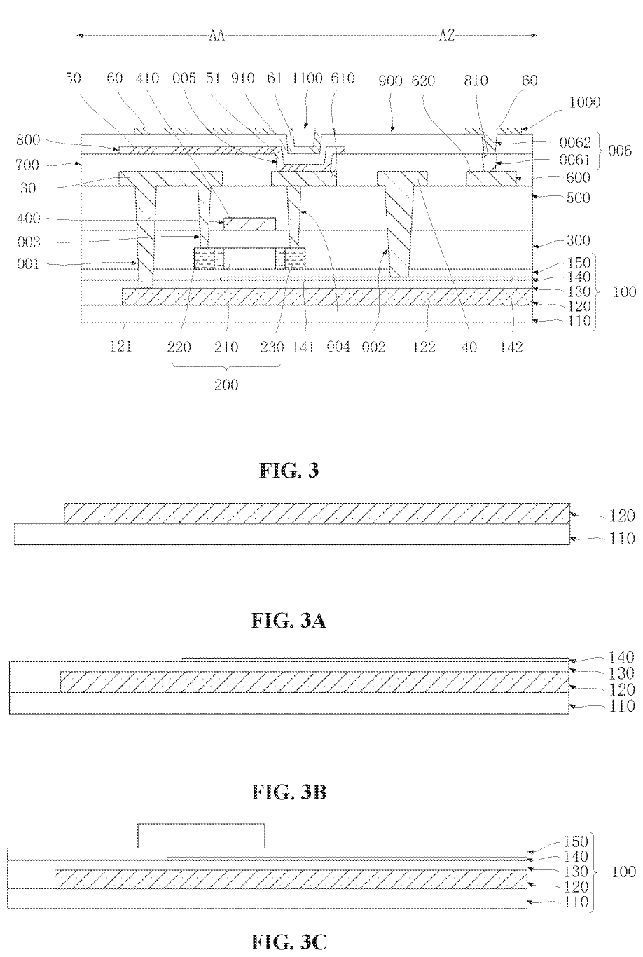

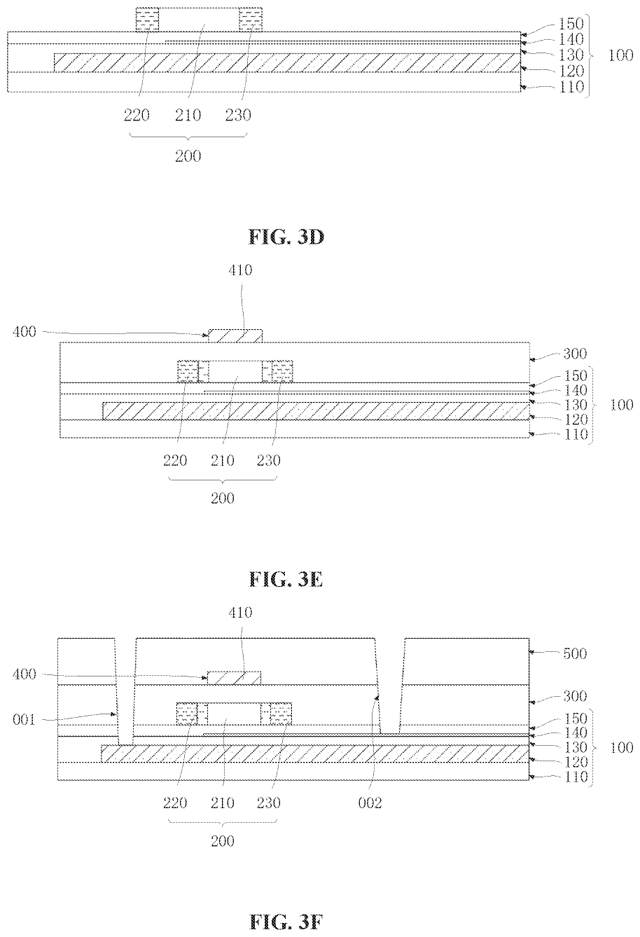

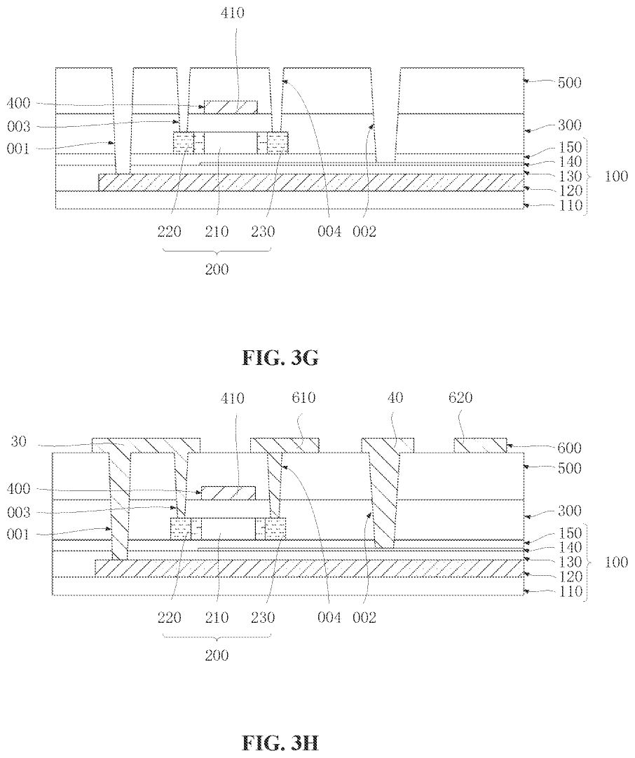

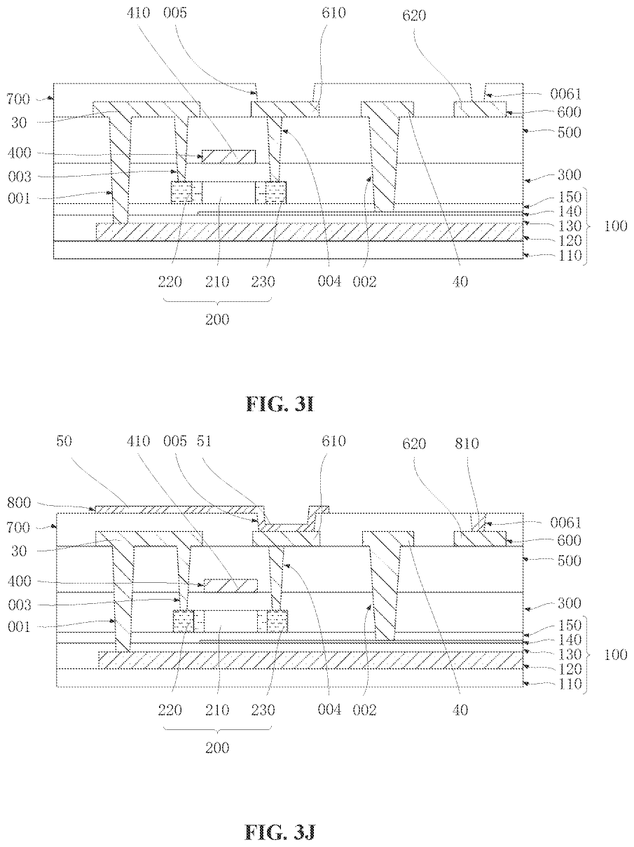

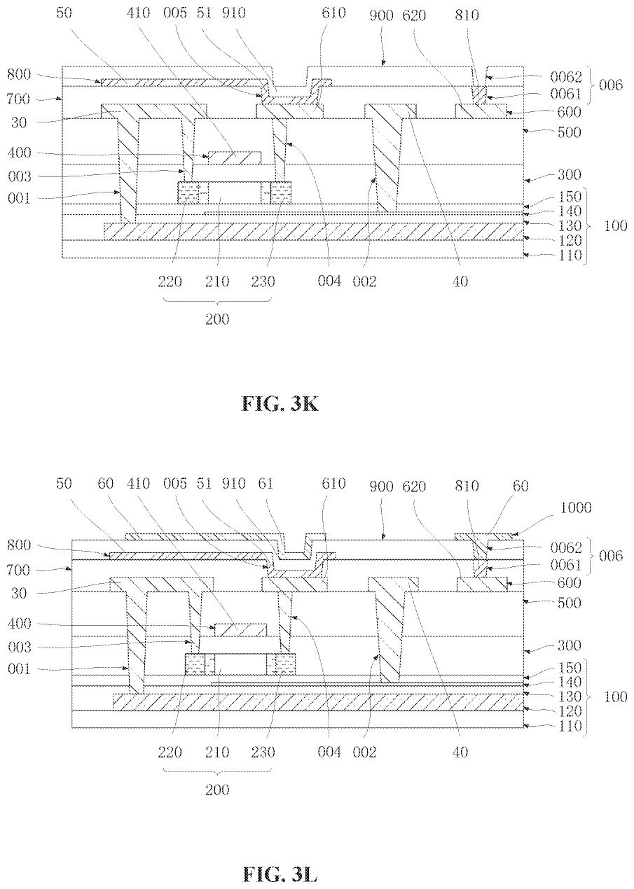

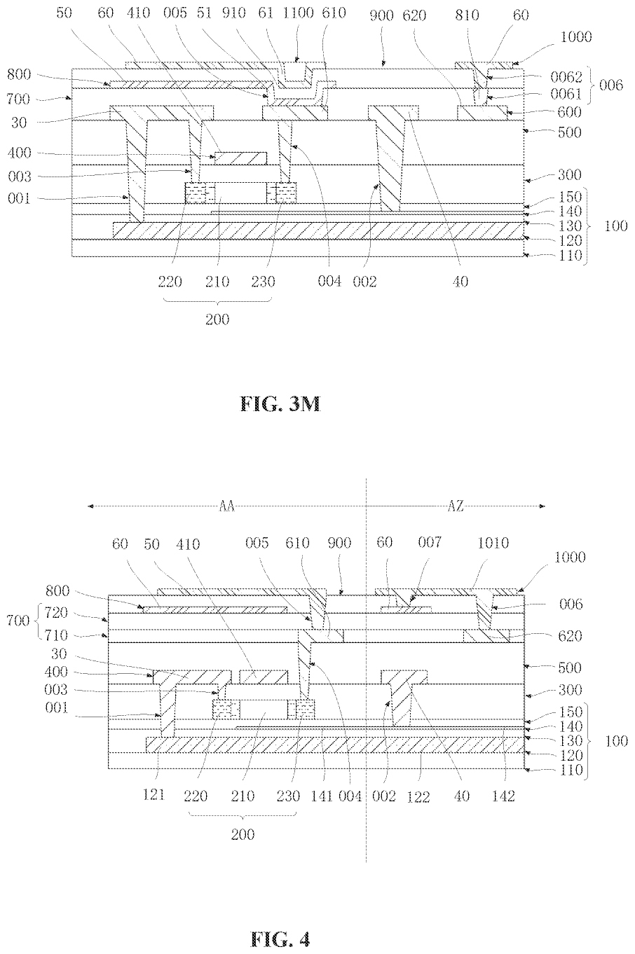

FIG. 3 is a schematic diagram of the second structure of an array substrate provided by an embodiment of the present application.

FIG. 3A to FIG. 3M are flowcharts of structural processes of manufacturing the array substrate shown in FIG. 3.

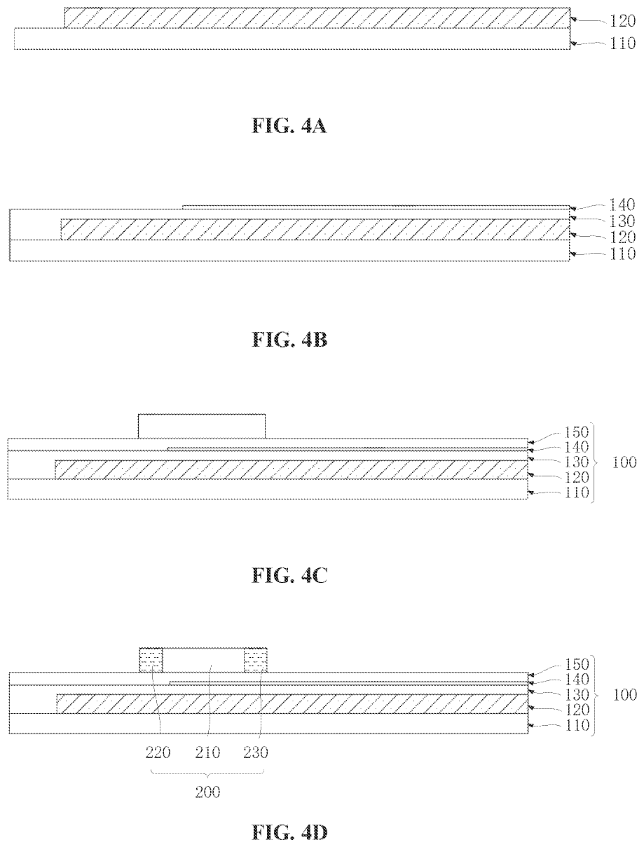

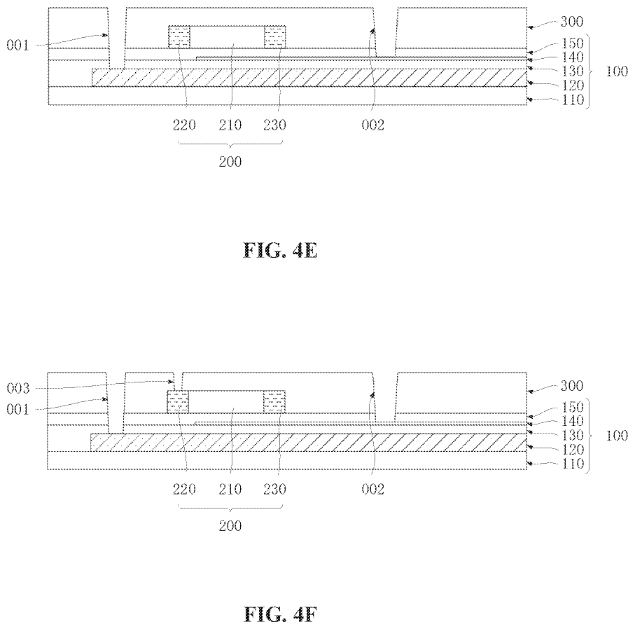

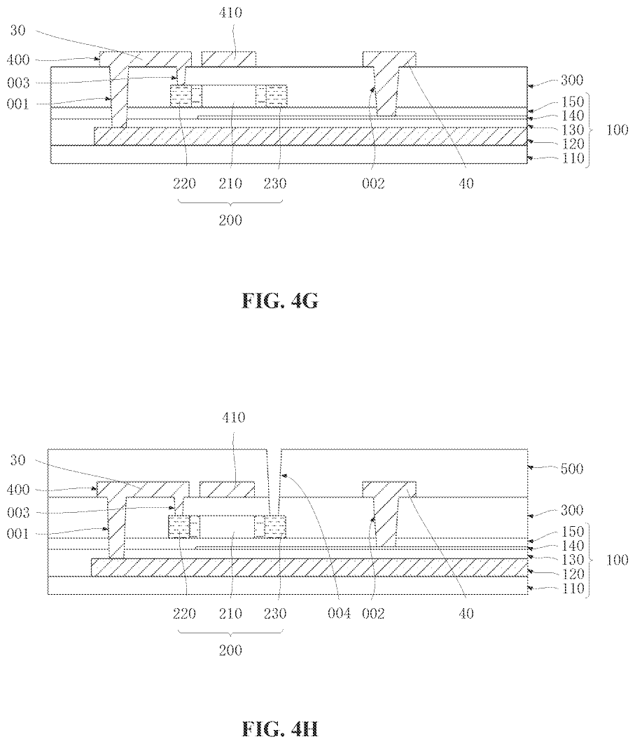

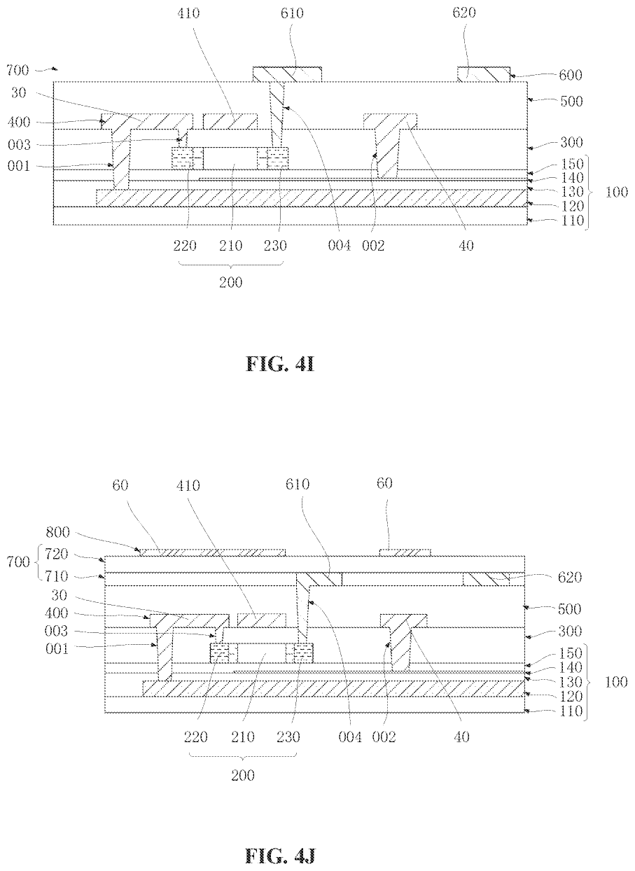

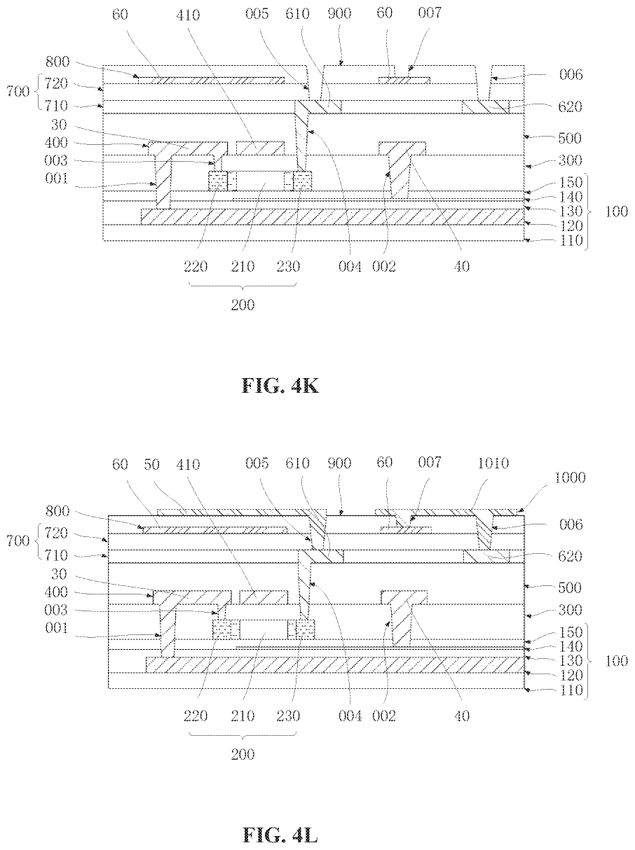

FIG. 4 is a schematic diagram of the third structure of an array substrate provided by an embodiment of the present application.

FIG. 4A to FIG. 4L are flowcharts of structural processes of manufacturing the array substrate shown in FIG. 4.

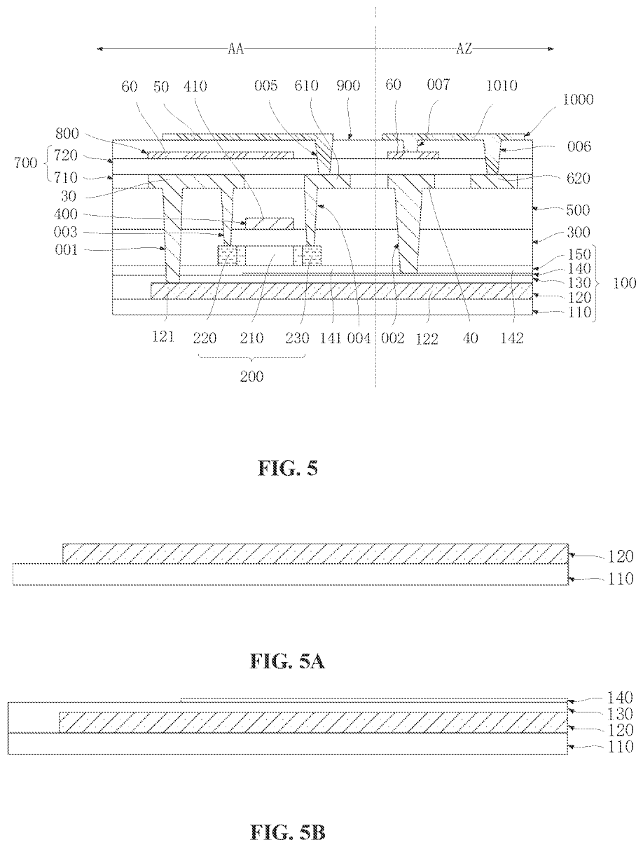

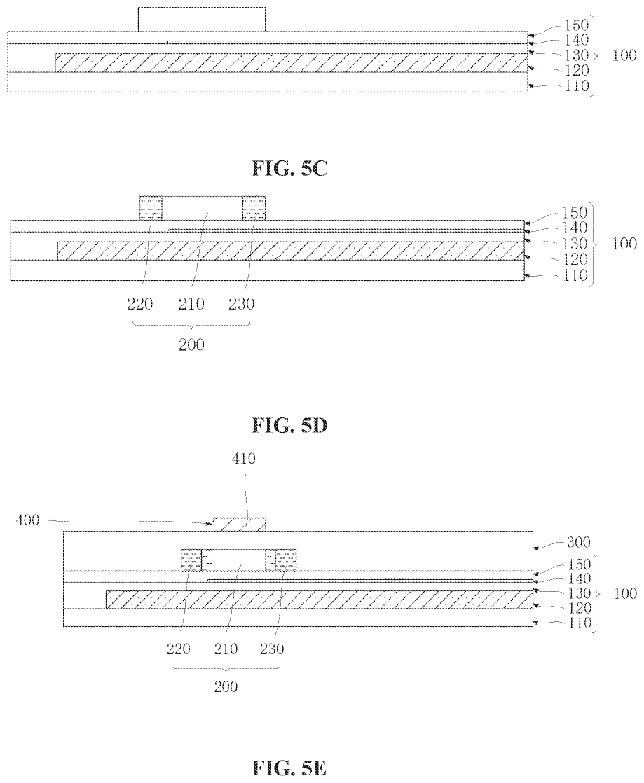

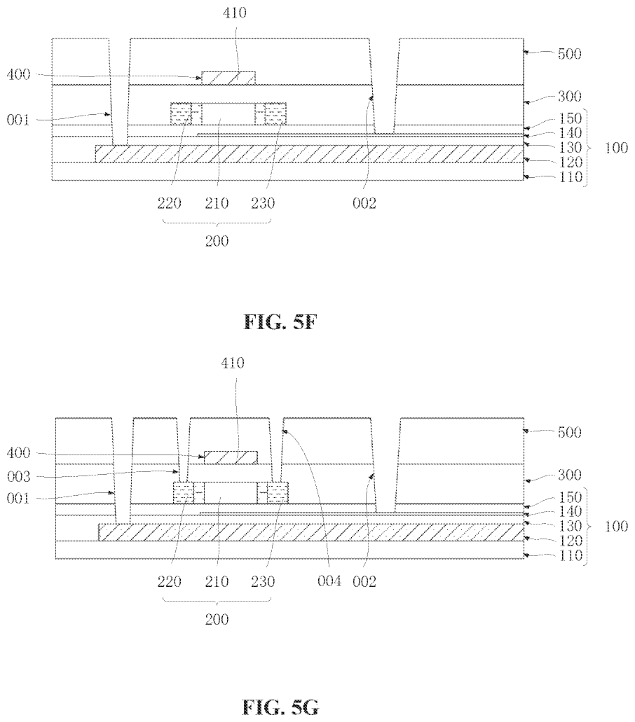

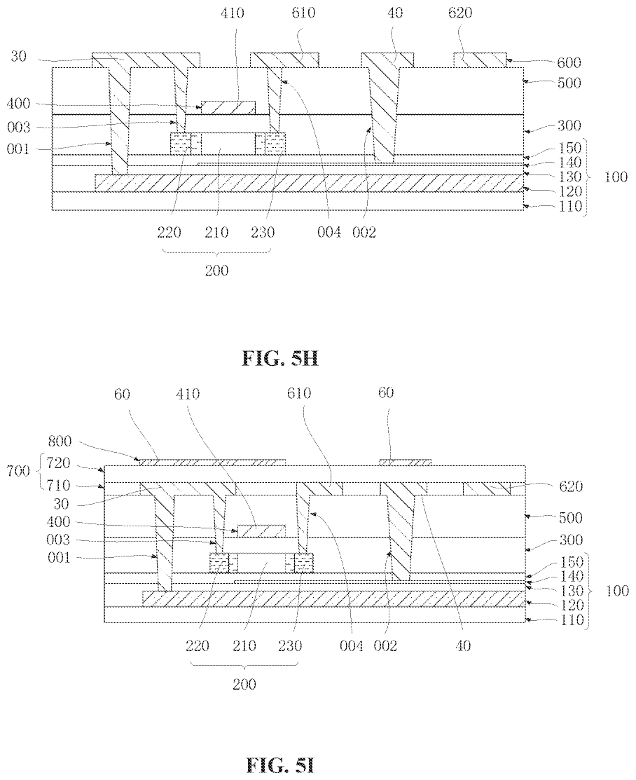

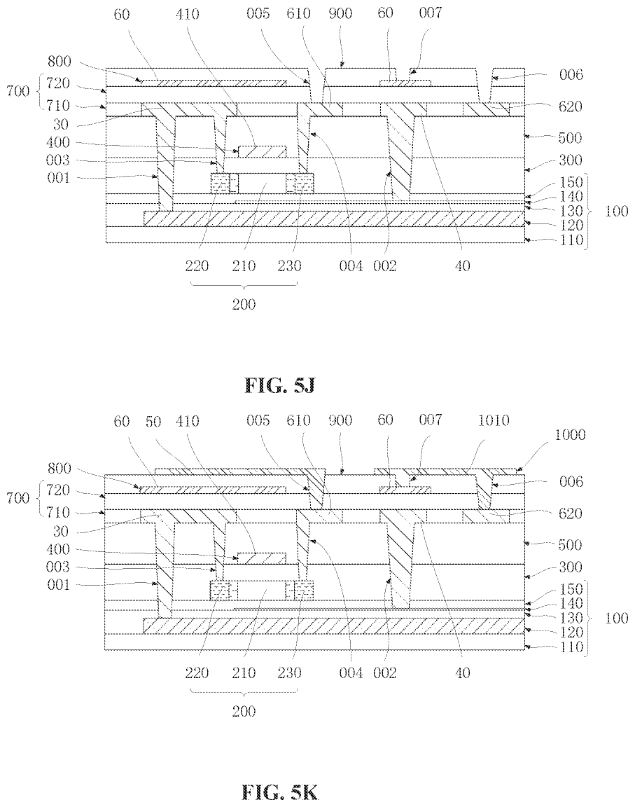

FIG. 5 is a schematic diagram of the fourth structure of an array substrate provided by an embodiment of the present application.

FIG. 5A to FIG. 5K are flowcharts of structural processes of manufacturing the array substrate shown in FIG. 5.

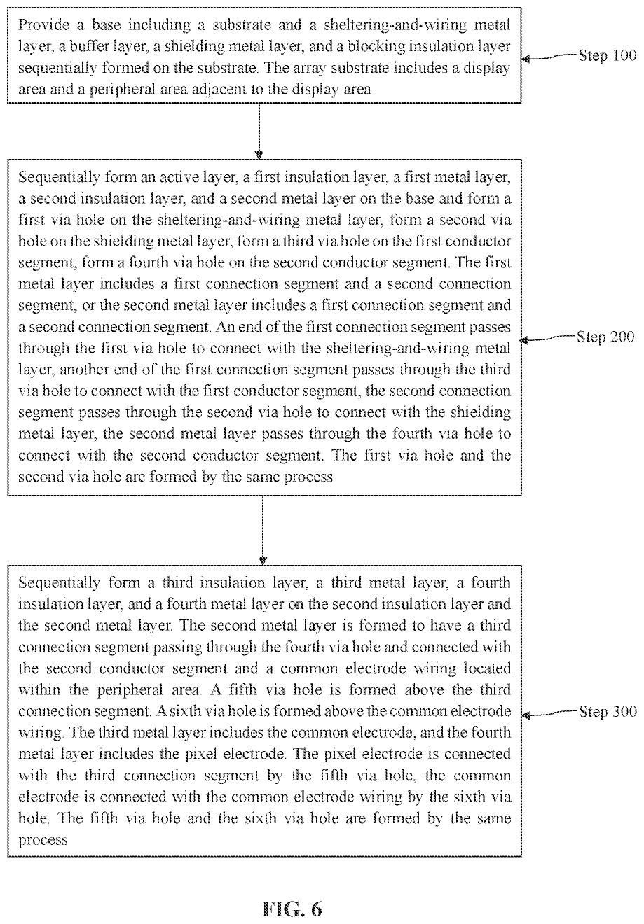

FIG. 6 is a flowchart of a manufacturing method of an array substrate provided by an embodiment of the present application.

### DETAILED DESCRIPTION OF EMBODIMENTS

### Embodiments of Invention

The following description of the embodiments with reference to the accompanying drawings is used to illustrate particular embodiments of the present disclosure. The directional terms referred in the present disclosure, such as “upper”, “lower”, “front”, “back”, “left”, “right”, “inner”, “outer”, “side surface”, etc. are only directions with regard to the accompanying drawings. Therefore, the directional terms used for describing and illustrating the present disclosure are not intended to limit the present disclosure. In the drawings, units with similar structures are indicated by the same reference number.

In the description of the present application, it should be understood that the terms “first” and “second” are used for descriptive purposes only and are not to be construed as indicating or implying relative importance or implicit indication of the number of indicated technical features. Therefore, the number of “first”, “second” features may be explicitly or implicitly included in one or more of the described features. In the description of the present application, the meaning of “multiple” is two or more than two, unless otherwise specifically defined.

In the description of the present application, it should be noted that the terms “installation”, “interconnection”, and “connection” should be understood broadly, unless otherwise clearly defined and limited. For example, it may be fixed connection or detachable connection, or integrated connection, it may be mechanical connection, electrical connection or intercommunication, it may be direct connection or indirect connection through an intermediate medium, or it may be internal communication of two components or mutual interaction of two components. For those with ordinary skill in the art, specific meanings of the above terms in the present application can be understood on a case-by-case basis.

The technical solutions of the present application are described in connection with specific embodiments.

Please refer to FIG. 2 to FIG. 5. Embodiments of the present application provide an array substrate including a display area AA and a peripheral area AZ adjacent to the display area AA. The array substrate includes:
a base 100 comprising stacked layers of a substrate 110, a sheltering-and-wiring metal layer 120, a buffer layer 130, a shielding metal layer 140, and a blocking insulation layer 150;
an active layer 200 disposed on the base 100, wherein the active layer 200 includes an active segment 210 and a first conductor segment 220 and a second conductor segment 230 disposed at two ends of the active segment 210;
a first insulation layer 300 disposed on the base 100 and the active layer 200;
a first metal layer 400 disposed on the first insulation layer 300;
a second insulation layer 500 disposed on the first insulation layer 300 and the first metal layer 400;
a second metal layer 600 disposed on the second insulation layer 500,
wherein the array substrate further includes a first via hole 001 defined above the sheltering-and-wiring metal layer 120, a second via hole 002 defined above the shielding metal layer 140, a third via hole 003 defined above the first conductor segment 220, a fourth via hole 004 defined above the second conductor segment 230, and a first connection segment 30 located within the display area AA and a second connection segment 40 located within the peripheral area AZ,
wherein an end of the first connection segment 30 passes through the first via hole 001 to connect with the sheltering-and-wiring metal layer 120, another end of the first connection segment 30 passes through the third via hole 003 to connect with the first conductor segment 220, the second connection segment 40 passes through the second via hole 002 to connect with the shielding metal layer 140, the second metal layer 600 passes through the fourth via hole 004 to connect with the second conductor segment 230,
wherein the first metal layer 400 includes the first connection segment 30 and the second connection segment 40; or
the second metal layer 600 includes the first connection segment 30 and the second connection segment 40.

It can be understood that, currently, in the high-resolution display panel such as resolution greater than 1000 ppi, as shown in FIG. 1, which is a schematic diagram of the structure of an array substrate of a high-resolution display panel. The array substrate includes stacked layers of a base 11, a sheltering layer 12, a first insulating layer 13, a shielding layer 14, a second insulating layer 15, a semiconductor layer 16, a third insulating layer 17, a first metal layer 18, a fourth insulating layer 19, a second metal layer 20, a fifth insulating layer 21, a third metal layer 22, a sixth insulating layer 23, a fourth metal layer 24, wherein the first metal layer 18 includes a first connecting portion 181 connecting with the semiconductor layer 16 and the sheltering layer 12 at both ends, respectively, and the second metal layer 20 includes a second connecting portion 201 respectively connecting with the semiconductor layer 16 and the third metal layer 22, a third connecting portion 202 connecting with the fourth metal layer 24, and a fourth connecting portion 203 connecting with the shielding layer 14. Apparently, the structure of the array substrate is more complex, and each functional film layer has to be connected to each other through different via holes, such that up to 15 photomask processes are required for the production of the array substrate. Such numerous process steps would cause higher production costs. In this embodiment, by disposing a first metal layer 400 to include a first connection segment 30 and a second connection segment 40, or disposing a second metal layer 600 to include a first connection segment 30 and a second connection segment 40, and combining the structure in which an end of the first connection segment 30 passes through a first via hole 001 to connect with a sheltering-and-wiring metal layer 120 with the structure in which the second connection segment 40 passes through a second via hole 002 to connect with the shielding metal layer 140, which represents that the first connection segment 30 and the second connection segment 40 are disposed at the same layer, a depth difference between the first via hole 001 defined above the sheltering-and-wiring metal layer 120 and the second via hole 002 defined above the shielding metal layer 140 can be smaller. In addition, the bottom of both the first via hole 001 and the second via hole 002 is a metal material layer such as the shielding metal layer 140 or the sheltering-and-wiring metal layer 120, which has a certain performance of preventing the over-etching from the etching gas, so that the first via hole 001 and the second via hole 002 can be made by the same photomask process, thereby reducing the number of photomasks and the production cost for manufacturing an array substrate.

It should be noted that as shown in FIG. 1, in the structure of the array substrate of prior art, the first connecting portion 181 and the fourth connecting portion 203 are respectively located at different film layers. The via hole connecting the first connecting portion 181 and the sheltering layer 12 and the via hole connecting the fourth connecting portion 203 and the shielding layer 14 have to be manufactured with different photomasks. In the present embodiment, by disposing the first connection segment 30 and the second connection segment 40 at the same layer and that the bottoms of the first via hole 001 and the second via hole 002 are made from metal materials, the structure has better performance on preventing over-etching from the etching gas, therefore the first via hole 001 and the second via hole 002 can be manufactured by the same photomask process. The materials of the shielding metal layer 140 and the sheltering-and-wiring metal layer 120 can be the same, the materials of the buffer layer 130, the blocking insulation layer 150, and the first insulation layer 300 can be the same, among which the materials of the buffer layer 130, the blocking insulation layer 150, and the first insulation layer 300 can be silicon oxide.

In an embodiment, please refer to FIG. 2, FIG. 4, FIG. 2A to FIG. 2I, and FIG. 4A to FIG. 4I. The first metal layer 400 includes the first connection segment 30 and the second connection segment 40;
the first via hole 001 passes through the first insulation layer 300, the blocking insulation layer 150, and the buffer layer 130, the second via hole 002 passes through the first insulation layer 300 and the blocking insulation layer 150, the third via hole 003 passes through the first insulation layer 300, and the fourth via hole 004 passes through the second insulation layer 500 and the first insulation layer 300.

It can be understood that the first metal layer 400 including the first connection segment 30 and the second connection segment 40 means that the first connection segment 30 and the second connection segment are disposed at the same layer at the position of the first metal layer 400. The first metal layer 400 further includes a gate electrode 410. The first connection segment 30, the second connection segment 40, and the gate electrode 410 can be formed by the same process. In specific, the first metal layer 400 includes the first connection segment 30 and the second connection segment 40, and the first via hole 001 passes through the first insulation layer 300, the blocking insulation layer 150, and the buffer layer 130, the second via hole 002 passes through the first insulation layer 300 and the blocking insulation layer 150, the third via hole 003 passes through the first insulation layer 300, the fourth via hole 004 passes through the second insulation layer 500 and the first insulation layer 300. The first via hole 001 and the second via hole 002 are integrally formed by the same process. Compared with the process of manufacturing the structure of the array substrate of prior art, one photomask is saved.

In an embodiment, please refer to FIG. 3, FIG. 5, FIG. 3A to FIG. 3H, and FIG. 5A to FIG. 5H. The second metal layer 600 includes the first connection segment 30 and the second connection segment 40;
the first via hole 001 passes through the second insulation layer 500, the first insulation layer 300, the blocking insulation layer 150, and the buffer layer 130, the second via hole 002 passes through the second insulation layer 500, the first insulation layer 300, and the blocking insulation layer 150, the third via hole 003 and the fourth via hole 004 both pass through the second insulation layer 500 and the first insulation layer 300.

It can be understood that the second metal layer 600 including the first connection segment 30 and the second connection segment 40 means that the first connection segment 30 and the second connection segment are disposed at the same layer at the position of the second metal layer 600. The first connection segment 30 and the second connection segment 40 can be integrally formed by the same process. In specific, please refer to FIG. 3, FIG. 5, FIG. 3A to FIG. 3H, and FIG. 5A to FIG. 5H, the first via hole 001 passes through the second insulation layer 500, the first insulation layer 300, the blocking insulation layer 150, and the buffer layer 130, the second via hole 002 passes through the second insulation layer 500, the first insulation layer 300, and the blocking insulation layer 150, the third via hole 003 and the fourth via hole 004 both pass through the second insulation layer 500 and the first insulation layer 300. The first via hole 001 and the second via hole 002 are integrally formed by the same process.

It is worth noting that when the second metal layer 600 includes the first connection segment 30 and the second connection segment 40, the third via hole 003 and the fourth via hole 004 both pass through the second insulation layer 500 and the first insulation layer 300. Also, the third via hole 003 is defined above the first conductor segment 220, the fourth via hole 004 is defined above the second conductor segment 230. At this time, the third via hole 003 and the fourth via hole 004 can be integrally formed by the same process. Compared with the process of manufacturing the structure of the array substrate of prior art, two photomasks are saved.

In an embodiment, please refer to FIG. 2 to FIG. 5, the sheltering-and-wiring metal layer 120 includes a sheltering portion 121 located within the display area AA and a data wiring 122 connected with the sheltering portion 121 and extending into the peripheral area AZ;
the first via hole 001 is opened above the sheltering portion 121, and an orthographic projection of the sheltering portion 121 on the substrate 110 covers an orthographic projection of the active layer 200 on the substrate 110.

It can be understood that the sheltering-and-wiring metal layer 120 including the sheltering portion 121 located within the display area AA and the data wiring 122 connected with the sheltering portion 121 and extending into the peripheral area AZ means that the data wiring 122 is disposed on the substrate 110, the orthographic projection of the sheltering portion 121 on the substrate 110 covers the orthographic projection of the active layer 200 on the substrate 110. The sheltering portion 121 is used for avoiding incident light of a side of the array substrate near the substrate 110 from irradiating into the active layer 200, causing a change in the electron mobility of the active layer 200, and thereby affecting the electrical performance of the array substrate. In addition, the first via hole 001 is opened above the sheltering portion 121, which means that the range of the orthographic projection of the sheltering portion 121 on the substrate 110 covers the area where the first via hole 001 locates.

In an embodiment, please refer to FIG. 2 to FIG. 5, the shielding metal layer 140 includes a shielding portion 141 located within the display area AA and a shielded wiring 142 connected with the shielding portion 141 and extending into the peripheral area AZ, the second via hole 002 is defined above the shielded wiring 142;
the shielding portion 141 is disposed between the active segment 210 and the

sheltering portion 121, and an orthographic projection of the shielding portion 141 on the substrate 110 covers an orthographic projection of the active segment 210 on the substrate 110.

It can be understood that the shielding metal layer 140 includes the shielding portion 141 located within the display area AA and the shielded wiring 142 connected with the shielding portion 141 and extending into the peripheral area AZ. The shielding portion 141 is disposed between the active segment 210 and the sheltering portion 121 to prevent the voltage on the sheltering-and-wiring metal from causing electrical interference to the active layer 200. In specific, the orthographic projection of the shielding portion 141 on the substrate 110 covers the orthographic projection of the active segment 210 on the substrate 110. The second via hole 002 is defined above the shielded wiring 142, and the range of the orthographic projection of the shielded wiring 142 on the substrate 110 covers the area where the second via hole 002 locates.

In an embodiment, please refer to FIG. 2 to FIG. 5, FIG. 2J to FIG. 2N, FIG. 3I to FIG. 3M, FIG. 4J to FIG. 4L, and FIG. 5J to FIG. 5K, the array substrate further includes:
a third insulation layer 700 disposed on the second insulation layer 500 and the second metal layer 600;
a third metal layer 800 disposed on the third insulation layer 700;
a fourth insulation layer 900 disposed on the third metal layer 800;
a fourth metal layer 1000 disposed on the fourth insulation layer 900;
the second metal layer 600 includes a third connection segment 610 passing through the fourth via hole 004 and connected with the second conductor segment 230 and a common electrode wiring 620 located within the peripheral area AZ, the array substrate includes a fifth via hole 005 defined above the third connection segment 610, a sixth via hole 006 defined above the common electrode wiring 620, a pixel electrode 50 connected with the third connection segment 610 by the fifth via hole 005, and a common electrode 60 connected with the common electrode wiring 620 by the sixth via hole 006;
wherein the third metal layer 800 includes the pixel electrode 50 and the fourth metal layer 1000 includes the common electrode 60; or
the third metal layer 800 includes the common electrode 60 and the fourth metal layer 1000 includes the pixel electrode 50.

It can be understood that the second metal layer 600 including the third connection segment 610 passing through the fourth via hole 004 and connected with the second conductor segment 230 and the common electrode wiring 620 located within the peripheral area AZ means that the third connection segment 610 and the common electrode wiring 620 are disposed at the same layer. The third connection segment 610 and the common electrode wiring 620 are integrally formed by the same process. The array substrate includes the fifth via hole 005 defined above the third connection segment 610, the sixth via hole 006 defined above the common electrode wiring 620, the pixel electrode 50 connected with the third connection segment 610 by the fifth via hole 005, and the common electrode 60 connected with the common electrode wiring 620 by the sixth via hole 006. The pixel electrode 50 and the common electrode 60 can be located at different film layers. In specific, the third metal layer 800 includes the pixel electrode 50 and the fourth metal layer 1000 includes the common electrode 60, or the third metal layer 800 includes the common electrode 60 and the fourth metal layer 1000 includes the pixel electrode 50.

It should be noted that in this embodiment, the common electrode 60 can include a part located at the display area AA and a part located at the peripheral area AZ, but not limited herein.

In an embodiment, please refer to FIG. 2 and FIG. 3, the third metal layer 800 includes the pixel electrode 50 and the fourth metal layer 1000 includes the common electrode 60;
the fifth via hole 005 passes through the third insulation layer 700, the sixth via hole 006 passes through the fourth insulation layer 900 and the third insulation layer 700, the pixel electrode 50 passes through the fifth via hole 005 to connect with the third connection segment 610, the common electrode 60 passes through the sixth via hole 006 to connect with the common electrode wiring 620;
a first concave portion 51 located in the fifth via hole 005 is defined by the pixel electrode 50, a second concave portion 910 located in the first concave portion 51 is defined by the fourth insulation layer 900, a third concave portion 61 located in the second concave portion 910 is defined by the common electrode 60;
the array substrate includes an organic insulation layer 1100 disposed in the third concave portion 61.

It can be understood that when the third metal layer 800 includes the pixel electrode 50 and the fourth metal layer 1000 includes the common electrode 60, the fifth via hole 005 passes through the third insulation layer 700, the sixth via hole 006 passes through the fourth insulation layer 900 and the third insulation layer 700, the pixel electrode 50 passes through the fifth via hole 005 to connect with the third connection segment 610, the common electrode 60 passes through the sixth via hole 006 to connect with the common electrode wiring 620.

It should be noted that the first concave portion 51 located in the fifth via hole 005 is defined by the pixel electrode 50, the second concave portion 910 located in the first concave portion 51 is defined by the fourth insulation layer 900, the third concave portion 61 located in the second concave portion 910 is defined by the common electrode 60, the array substrate includes the organic insulation layer 1100 disposed in the third concave portion 61. In the high-resolution display panel such as resolution greater than 1000 ppi, the pixels of the display panel are denser, so the distances between the pixels are smaller. In this embodiment, by disposing the organic insulation layer 1100 in the third concave portion 61, it is convenient to dispose a spacer column on the organic insulation layer 1100, thereby avoiding the problem that the spacer column cannot be disposed due to the denser pixels in the high-resolution display panel and achieving a reduction of the number of photomasks in manufacturing the array substrate and reducing the production cost of the array substrate on the basis of not affecting the performance of the array substrate.

In an embodiment, please refer to FIG. 2 and FIG. 3, the sixth via hole 006 includes a first sub-hole 0061 passing through the third insulation layer 700 and a second sub-hole 0062 passing through the fourth insulation layer 900 and communicating with the first sub-hole 0061;
the third metal layer 800 further includes a connecting portion 810 disposed in the first sub-hole 0061 and connected with the common electrode wiring 620, the common electrode 60 passes through the second sub-hole 0062 to connect with the connecting portion 810.

It can be understood that the sixth via hole 006 including the first sub-hole 0061 passing through the third insulation layer 700 and the second sub-hole 0062 passing through the fourth insulation layer 900 and communicating with the first sub-hole 0061 means that the first sub-hole 0061 and the fifth via hole 005 are both opened above the third insulation layer 700. The first sub-hole 0061 and the fifth via hole 005 can be integrally formed by the same photomask process. The second sub-hole 0062 and the second concave portion 910 are both opened above the fourth insulation layer 900. The second sub-hole 0062 and the second concave portion 910 can be integrally formed by the same photomask process. The second metal layer 600 further includes the connecting portion 810 disposed in the first sub-hole 0061 and connected with the common electrode wiring 620, which means that the connecting portion 810 and the third connection segment 610 in the second metal layer 600 are disposed at the same layer. The connecting portion 810 and the third connection segment 610 can be integrally formed by the same process.

In an embodiment, please refer to FIG. 4 and FIG. 5, the third metal layer 800 includes the common electrode 60 and the fourth metal layer 1000 includes the pixel electrode 50;
the fifth via hole 005 and the sixth via hole 006 both pass through the third insulation layer 700 and the fourth insulation layer 900, the pixel electrode 50 passes through the fifth via hole 005 to connect with the third connection segment 610;
the array substrate further includes a seventh via hole 007 defined above the common electrode 60, the seventh via hole 007 passes through the fourth insulation layer 900 and locates within the peripheral area AZ, the fourth metal layer 1000 further includes a fourth connection segment 1010, an end of the fourth connection segment 1010 passes through the sixth via hole 006 to connect with the common electrode wiring 620, and another end of the fourth connection segment 1010 passes through the sixth via hole 006 to connect with the common electrode wiring 620.

It can be understood that the third metal layer 800 includes the common electrode 60 and the fourth metal layer 1000 includes the pixel electrode 50. The fifth via hole 005 and the sixth via hole 006 both pass through the third insulation layer 700 and the fourth insulation layer 900, the pixel electrode 50 passes through the fifth via hole 005 to connect with the third connection segment 610. At this time, the array substrate further includes the seventh via hole 007 defined above the common electrode 60, the seventh via hole 007 passes through the fourth insulation layer 900 and locates within the peripheral area AZ, the fourth metal layer 1000 further includes the fourth connection segment 1010, an end of the fourth connection segment 1010 passes through the sixth via hole 006 to connect with the common electrode wiring 620, and another end of the fourth connection segment 1010 passes through the sixth via hole 006 to connect with the common electrode wiring 620. The fourth connection segment 1010 and the pixel electrode 50 are disposed at the same layer. The same layer of the fourth connection segment 1010 and the pixel electrode 50 can be integrally formed by the same process. The common electrode wiring 620 and the common electrode 60 are bridged by the fourth connection segment 1010.

It should be noted that the seventh via hole 007 is defined above the common electrode 60, the fifth via hole 005 is defined above the pixel electrode 50, the sixth via hole 006 is defined above the common electrode wiring 620, so that it is convenient for the seventh via hole 007, the sixth via hole 006, and the fifth via hole 005 to be integrally formed by the same photomask process, thereby further reducing the number of photomasks in manufacturing the array substrate and reducing the production cost of the array substrate.

In an embodiment, please refer to FIG. 4 and FIG. 5, the third insulation layer 700 includes a flat insulation sublayer 710 disposed on the second insulation layer 500 and an interlayer insulation sublayer 720 disposed on the flat insulation sublayer 710 and the second metal layer 600;
a thickness of the flat insulation sublayer 710 is less than or equal to a thickness of the second metal layer 600.

It can be understood that the material of the flat insulation sublayer 710 is organic material. During the manufacturing of the flat insulation sublayer 710, an organic insulating material layer covering the second metal layer 600 can be formed on the second insulation layer 500 and the second metal layer 600, and then a patterning step, such as a photolithography process, is used for eliminating the thickness of the entirety of the organic insulating material layer to form the flat insulation sublayer 710. The thickness of the flat insulation sublayer 710 is less than or equal to the thickness of the second metal layer 600. Therefore, no additional photomask has to be added during the manufacturing of the flat insulation sublayer 710. In this embodiment, the thickness of the flat insulation sublayer 710 is equal to the thickness of the second metal layer 600.

Embodiments of the present application also provide a manufacturing method of an array substrate. Please refer to FIG. 6, FIG. 2A to FIG. 2I, FIG. 3A to FIG. 3H, FIG. 4A to FIG. 4I, and FIG. 5A to FIG. 5H. The manufacturing method includes steps as follows.

A step 100 is to provide a base 100 including a substrate 110 and a sheltering-and-wiring metal layer 120, a buffer layer 130, a shielding metal layer 140, and a blocking insulation layer 150 sequentially formed on the substrate 110. The array substrate includes a display area AA and a peripheral area AZ adjacent to the display area AA.

A step 200 is to sequentially form an active layer 200, a first insulation layer 300, a first metal layer 400, a second insulation layer 500, and a second metal layer 600 on the base 100 and form a first via hole 001 on the sheltering-and-wiring metal layer 120, form a second via hole 002 on the shielding metal layer 140, form a third via hole 003 on the first conductor segment 220, form a fourth via hole 004 on the second conductor segment 230. The first metal layer 400 includes a first connection segment 30 and a second connection segment 40, or the second metal layer 600 includes a first connection segment 30 and a second connection segment 40. An end of the first connection segment 30 passes through the first via hole 001 to connect with the sheltering-and-wiring metal layer 120, another end of the first connection segment 30 passes through the third via hole 003 to connect with the first conductor segment 220, the second connection segment 40 passes through the second via hole 002 to connect with the shielding metal layer 140, the second metal layer 600 passes through the fourth via hole 004 to connect with the second conductor segment 230. The first via hole 001 and the second via hole 002 are formed by the same process.

In the manufacturing method of the array substrate provided by the embodiments of the present application, please refer to FIG. 6, FIG. 4J to FIG. 4L, and FIG. 5I to FIG. 5K. The manufacturing method also includes steps as follows.

A step 300 is to sequentially form a third insulation layer 700, a third metal layer 800, a fourth insulation layer 900, and a fourth metal layer 1000 on the second insulation layer 500 and the second metal layer 600. The second metal layer 600 is formed to have a third connection segment 610 passing through the fourth via hole 004 and connected with the second conductor segment 230 and a common electrode wiring 620 located within the peripheral area AZ. A fifth via hole 005 is formed above the third connection segment 610. A sixth via hole 006 is formed above the common electrode wiring 620. The third metal layer 800 includes the common electrode 60 and the fourth metal layer 1000 includes the pixel electrode 50. The pixel electrode 50 is connected with the third connection segment 610 by the fifth via hole 005, the common electrode is connected with the common electrode wiring 620 by the sixth via hole 006. The fifth via hole 005 and the sixth via hole 006 are formed by the same process.

Embodiments of the present application also provide a display panel. The display panel includes an array substrate as described in any one of the above-mentioned embodiments.

In the embodiments of the present application, by disposing a first metal layer 400 to include a first connection segment 30 and a second connection segment 40 or disposing a second metal layer 600 to include a first connection segment 30 and a second connection segment 40, and combining the structure that an end of the first connection segment 30 passes through a first via hole 001 to connect with a sheltering-and-wiring metal layer 120 with the structure that the second connection segment 40 passes through a second via hole 002 to connect with the shielding metal layer 140, which represents that the first connection segment 30 and the second connection segment 40 are disposed at the same layer, such that a depth difference between the first via hole 001 defined above the sheltering-and-wiring metal layer 120 and the second via hole 002 defined above the shielding metal layer 140 is smaller. In addition, the bottom of both the first via hole 001 and the second via hole 002 is a metal material layer such as shielding metal layer 140 or sheltering-and-wiring metal layer 120, which has a certain performance of preventing the over-etching from the etching gas, so that the first via hole 001 and the second via hole 002 can be made by the same photomask process, thereby reducing the number of photomasks and the production cost for manufacturing an array substrate.

In summary, although the present invention has been disclosed above with preferred embodiments, the preferred embodiments mentioned above are not intended to limit the present invention. Those of ordinary skill in the art may make various changes and modifications without departing from the spirit and scope of the present invention. Therefore, the scope of protection of the present invention is subject to the scope defined by the claims.

What is claimed is:

1. An array substrate, wherein the array substrate comprises a display area and a peripheral area adjacent to the display area, and the array substrate comprises:
a base comprising stacked layers of a substrate, a sheltering-and-wiring metal layer, a buffer layer, a shielding metal layer, and a blocking insulation layer;
an active layer disposed on the base, wherein the active layer comprises an active segment and a first conductor segment and a second conductor segment disposed at two ends of the active segment;
a first insulation layer disposed on the base and the active layer;
a first metal layer disposed on the first insulation layer;
a second insulation layer disposed on the first insulation layer and the first metal layer;
a second metal layer disposed on the second insulation layer,
wherein the array substrate further comprises a first via hole defined above the sheltering-and-wiring metal layer, a second via hole defined above the shielding metal layer, a third via hole defined above the first conductor segment, a fourth via hole defined above the second conductor segment, and a first connection segment located within the display area and a second connection segment located within the peripheral area,
wherein an end of the first connection segment passes through the first via hole to connect with the sheltering-and-wiring metal layer, another end of the first connection segment passes through the third via hole to connect with the first conductor segment, the second connection segment passes through the second via hole to connect with the shielding metal layer, the second metal layer passes through the fourth via hole to connect with the second conductor segment,
wherein the first metal layer comprises the first connection segment and the second connection segment; or
the second metal layer comprises the first connection segment and the second connection segment.

2. The array substrate as claimed in claim 1, wherein the first metal layer comprises the first connection segment and the second connection segment;
the first via hole passes through the first insulation layer, the blocking insulation layer, and the buffer layer, the second via hole passes through the first insulation layer and the blocking insulation layer, the third via hole passes through the first insulation layer, and the fourth via hole passes through the second insulation layer and the first insulation layer.

3. The array substrate as claimed in claim 1, wherein the second metal layer comprises the first connection segment and the second connection segment;
the first via hole passes through the second insulation layer, the first insulation layer, the blocking insulation layer, and the buffer layer, the second via hole passes through the second insulation layer, the first insulation layer, and the blocking insulation layer, the third via hole and the fourth via hole both pass through the second insulation layer and the first insulation layer.

4. The array substrate as claimed in claim 1, wherein the sheltering-and-wiring metal layer comprises a sheltering portion located within the display area and a data wiring connected with the sheltering portion and extending into the peripheral area;
the first via hole is opened above the sheltering portion, and an orthographic projection of the sheltering portion on the substrate covers an orthographic projection of the active layer on the substrate.

5. The array substrate as claimed in claim 4, wherein the shielding metal layer comprises a shielding portion located within the display area and a shielded wiring connected with the shielding portion and extending into the peripheral area, the second via hole is defined above the shielded wiring;
the shielding portion is disposed between the active segment and the sheltering portion, and an orthographic projection of the shielding portion on the substrate covers an orthographic projection of the active segment on the substrate.

6. The array substrate as claimed in claim 1, wherein the array substrate further comprises:
a third insulation layer disposed on the second insulation layer and the second metal layer;
a third metal layer disposed on the third insulation layer;
a fourth insulation layer disposed on the third metal layer;
a fourth metal layer disposed on the fourth insulation layer;
the second metal layer comprises a third connection segment passing through the fourth via hole and connected with the second conductor segment and a common electrode wiring located within the peripheral area, the array substrate comprises a fifth via hole defined above the third connection segment, a sixth via hole defined above the common electrode wiring, a pixel electrode connected with the third connection segment by the fifth via hole, and a common electrode connected with the common electrode wiring by the sixth via hole;
wherein the third metal layer comprises the pixel electrode and the fourth metal layer comprises the common electrode; or
the third metal layer comprises the common electrode and the fourth metal layer comprises the pixel electrode.

7. The array substrate as claimed in claim 6, wherein the third metal layer comprises the pixel electrode and the fourth metal layer comprises the common electrode;
the fifth via hole passes through the third insulation layer, the sixth via hole passes through the fourth insulation layer and the third insulation layer, the pixel electrode passes through the fifth via hole to connect with the third connection segment, the common electrode passes through the sixth via hole to connect with the common electrode wiring;
a first concave portion located in the fifth via hole is defined by the pixel electrode, a second concave portion located in the first concave portion is defined by the fourth insulation layer, a third concave portion located in the second concave portion is defined by the common electrode;
the array substrate comprises an organic insulation layer disposed in the third concave portion.

8. The array substrate as claimed in claim 7, wherein the sixth via hole comprises a first sub-hole passing through the third insulation layer and a second sub-hole passing through the fourth insulation layer and communicating with the first sub-hole;
the third metal layer further comprises a connecting portion disposed in the first sub-hole and connected with the common electrode wiring, the common electrode passes through the second sub-hole to connect with the connecting portion.

9. The array substrate as claimed in claim 6, wherein the third metal layer comprises the common electrode and the fourth metal layer comprises the pixel electrode;
the fifth via hole and the sixth via hole both pass through the third insulation layer and the fourth insulation layer, the pixel electrode passes through the fifth via hole to connect with the third connection segment;
the array substrate further comprises a seventh via hole defined above the common electrode, the seventh via hole passes through the fourth insulation layer and locates within the peripheral area, the fourth metal layer further comprises a fourth connection segment, an end of the fourth connection segment passes through the sixth via hole to connect with the common electrode wiring, and another end of the fourth connection segment passes through the sixth via hole to connect with the common electrode wiring.

10. The array substrate as claimed in claim 9, wherein the third insulation layer comprises a flat insulation sublayer disposed on the second insulation layer and an interlayer insulation sublayer disposed on the flat insulation sublayer and the second metal layer;
a thickness of the flat insulation sublayer is less than or equal to a thickness of the second metal layer.

11. A display panel, wherein the display panel comprises an array substrate, the array substrate comprises a display area and a peripheral area adjacent to the display area, and the array substrate comprises:
a base comprising stacked layers of a substrate, a sheltering-and-wiring metal layer, a buffer layer, a shielding metal layer, and a blocking insulation layer;
an active layer disposed on the base, wherein the active layer comprises an active segment and a first conductor segment and a second conductor segment disposed at two ends of the active segment;
a first insulation layer disposed on the base and the active layer;
a first metal layer disposed on the first insulation layer;
a second insulation layer disposed on the first insulation layer and the first metal layer;
a second metal layer disposed on the second insulation layer,
wherein the array substrate further comprises a first via hole defined above the sheltering-and-wiring metal layer, a second via hole defined above the shielding metal layer, a third via hole defined above the first conductor segment, a fourth via hole defined above the second conductor segment, and a first connection segment located within the display area and a second connection segment located within the peripheral area,
wherein an end of the first connection segment passes through the first via hole to connect with the sheltering-and-wiring metal layer, another end of the first connection segment passes through the third via hole to connect with the first conductor segment, the second connection segment passes through the second via hole to connect with the shielding metal layer, the second metal layer passes through the fourth via hole to connect with the second conductor segment,
wherein the first metal layer comprises the first connection segment and the second connection segment; or
the second metal layer comprises the first connection segment and the second connection segment.

12. The display panel as claimed in claim 11, wherein the first metal layer comprises the first connection segment and the second connection segment;
the first via hole passes through the first insulation layer, the blocking insulation layer, and the buffer layer, the second via hole passes through the first insulation layer and the blocking insulation layer, the third via hole passes through the first insulation layer, and the fourth via hole passes through the second insulation layer and the first insulation layer.

13. The display panel as claimed in claim 11, wherein the second metal layer comprises the first connection segment and the second connection segment;
the first via hole passes through the second insulation layer, the first insulation layer, the blocking insulation layer, and the buffer layer, the second via hole passes through the second insulation layer, the first insulation layer, and the blocking insulation layer, the third via hole and the fourth via hole both pass through the second insulation layer and the first insulation layer.

14. The display panel as claimed in claim 11, wherein the sheltering-and-wiring metal layer comprises a sheltering portion located within the display area and a data wiring connected with the sheltering portion and extending into the peripheral area;
the first via hole is opened above the sheltering portion, and an orthographic projection of the sheltering portion on the substrate covers an orthographic projection of the active layer on the substrate.

15. The display panel as claimed in claim 14, wherein the shielding metal layer comprises a shielding portion located within the display area and a shielded wiring connected with the shielding portion and extending into the peripheral area, the second via hole is defined above the shielded wiring;
the shielding portion is disposed between the active segment and the sheltering portion, and an orthographic projection of the shielding portion on the substrate covers an orthographic projection of the active segment on the substrate.

16. The display panel as claimed in claim 11, wherein the array substrate further comprises:
a third insulation layer disposed on the second insulation layer and the second metal layer;
a third metal layer disposed on the third insulation layer;
a fourth insulation layer disposed on the third metal layer;
a fourth metal layer disposed on the fourth insulation layer;
the second metal layer comprises a third connection segment passing through the fourth via hole and connected with the second conductor segment and a common electrode wiring located within the peripheral area, the array substrate comprises a fifth via hole defined above the third connection segment, a sixth via hole defined above the common electrode wiring, a pixel electrode connected with the third connection segment by the fifth via hole, and a common electrode connected with the common electrode wiring by the sixth via hole;
wherein the third metal layer comprises the pixel electrode and the fourth metal layer comprises the common electrode; or
the third metal layer comprises the common electrode and the fourth metal layer comprises the pixel electrode.

17. The display panel as claimed in claim 16, wherein the third metal layer comprises the pixel electrode and the fourth metal layer comprises the common electrode;
the fifth via hole passes through the third insulation layer, the sixth via hole passes through the fourth insulation layer and the third insulation layer, the pixel electrode passes through the fifth via hole to connect with the third connection segment, the common electrode passes through the sixth via hole to connect with the common electrode wiring;
a first concave portion located in the fifth via hole is defined by the pixel electrode, a second concave portion located in the first concave portion is defined by the fourth insulation layer, a third concave portion located in the second concave portion is defined by the common electrode;
the array substrate comprises an organic insulation layer disposed in the third concave portion.

18. The display panel as claimed in claim 17, wherein the sixth via hole comprises a first sub-hole passing through the third insulation layer and a second sub-hole passing through the fourth insulation layer and communicating with the first sub-hole;
the third metal layer further comprises a connecting portion disposed in the first sub-hole and connected with the common electrode wiring, the common electrode passes through the second sub-hole to connect with the connecting portion.

19. The display panel as claimed in claim 16, wherein the third metal layer comprises the common electrode and the fourth metal layer comprises the pixel electrode;
the fifth via hole and the sixth via hole both pass through the third insulation layer and the fourth insulation layer, the pixel electrode passes through the fifth via hole to connect with the third connection segment;
the array substrate further comprises a seventh via hole defined above the common electrode, the seventh via hole passes through the fourth insulation layer and locates within the peripheral area, the fourth metal layer further comprises a fourth connection segment, an end of the fourth connection segment passes through the sixth via hole to connect with the common electrode wiring, and another end of the fourth connection segment passes through the sixth via hole to connect with the common electrode wiring.

20. The display panel as claimed in claim 19, wherein the third insulation layer comprises a flat insulation sublayer disposed on the second insulation layer and an interlayer insulation sublayer disposed on the flat insulation sublayer and the second metal layer;
a thickness of the flat insulation sublayer is less than or equal to a thickness of the second metal layer.
